(19) United States
(12) Patent Application Publication
(10) Pub. No.: US 2018/0040502 A1
(43) Pub. Date: Feb. 8, 2018

(54) APPARATUS FOR PROCESSING WAFER-SHAPED ARTICLES

(71) Applicant: LAM RESEARCH AG, VILLACH (AT)

(72) Inventors: Shih-Chung KON, Fremont, CA (US); Milan PLISKA, VILLACH (AT); Bernhard LOIDL, VILLACH (AT); Michael BRUGGER, MILLSTATT (AT)

(73) Assignee: LAM RESEARCH AG

(21) Appl. No.: 15/230,254

(22) Filed: Aug. 5, 2016

(51) Int. Cl. H01L 21/683; H01L 21/67; H01L 21/687

(52) U.S. Cl. CPC H01L 21/6838; H01L 21/68764; H01L 21/68785; H01L 21/68792; H01L 21/68735; H01L 21/67115; H01L 21/6708

(57) ABSTRACT

An apparatus for processing wafer-shaped articles comprises a rotary chuck having a series of contact elements surrounding a wafer-shaped article when mounted on the rotary chuck. A non-rotating plate is positioned interiorly of the series of contact elements. The plate includes a gas supply that is configured to supply gas so as to support a wafer-shaped article without contacting the non-rotating plate according to the Bernoulli principle.

### BACKGROUND OF THE INVENTION

### 1. Field of the Invention

The invention relates generally to an apparatus for processing wafer-shaped articles, such as semiconductor wafers.

### 2. Description of Related Art

Semiconductor wafers are subjected to various surface treatment processes such as etching, cleaning, polishing and material deposition. To accommodate such processes, a single wafer may be supported in relation to one or more treatment fluid nozzles by a chuck associated with a rotatable carrier, as is described for example in U.S. Pat. Nos. 4,903,717 and 5,513,668.

The chucks of the aforementioned patents support a wafer on a cushion of gas, according to Bernoulli's principle. However, in conventional Bernoulli chucks it is difficult or inconvenient to dispense liquid onto the peripheral region of the underside of a wafer.

### SUMMARY OF THE INVENTION

In one aspect, the present invention relates to an apparatus for processing wafer-shaped articles comprises a rotary chuck having a series of contact elements surrounding a wafer-shaped article when mounted on the rotary chuck. A non-rotating plate is positioned interiorly of the series of contact elements. The plate includes a gas supply that is configured to supply gas so as to support a wafer-shaped article without contacting the non-rotating plate according to the Bernoulli principle.

In preferred embodiments of the apparatus according to the present invention, the gas supply is an annular gas supply directed radially outwardly in relation to an axis of rotation of the rotary chuck.

In preferred embodiments of the apparatus according to the present invention, the non-rotating plate is secured on a stationary central post.

In preferred embodiments of the apparatus according to the present invention, the non-rotating plate is generally circular and mounted coaxially with an axis of rotation of the rotary chuck, the rotary chuck having a diameter that is greater than the predetermined diameter.

In preferred embodiments of the apparatus according to the present invention, the contact surface faces radially inwardly in the contact position and is parallel to the rotational axis of the rotary chuck.

In preferred embodiments of the apparatus according to the present invention, the rotary chuck comprises a chuck base body mounted for rotation about the central post, the chuck base body surrounding a fluid distribution manifold comprising the non-rotating plate.

In preferred embodiments of the apparatus according to the present invention, each of the series of contact elements comprises a shaft projecting from the chuck base body, and the contact surface projects radially inwardly from a distal end of the shaft so as to overlie the non-rotating plate in the contact position.

In preferred embodiments of the apparatus according to the present invention, the gas supply is an annular array of gas supply nozzles comprising a circular series of bores that open on a surface of the non-rotating plate that faces a wafer-shaped article when mounted on the rotary chuck, each of the circular series of bores extending from the surface interiorly of the non-rotating plate at an oblique angle relative to an axis of rotation of the rotary chuck.

In preferred embodiments of the apparatus according to the present invention, the non-rotating plate further comprises a plurality of liquid-dispensing nozzles positioned radially outwardly of the gas supply, and directed toward an edge region of a wafer-shaped article when positioned on the rotary chuck.

In preferred embodiments of the apparatus according to the present invention, the plurality of liquid dispensing nozzles are comprised by a modular nozzle block that is attachable to and detachable from the non-rotating plate.

In preferred embodiments of the apparatus according to the present invention, the series of contact elements is a series of pins, each of the series of pins being rotatable about a respective pin axis so as to move a contact surface of a corresponding pin from a radially outer loading position to a radially inner contact position.

In preferred embodiments of the apparatus according to the present invention, a liquid dispenser is positioned so as to dispense liquid onto a side of a wafer-shaped article that faces away from the non-rotating plate when positioned on the rotary chuck.

In preferred embodiments of the apparatus according to the present invention, the gas supply comprises an annular array of gas supply nozzles or an annular gas supply nozzle.

In preferred embodiments of the apparatus according to the present invention, a supply of inert gas is in communication with the gas supply.

In preferred embodiments of the apparatus according to the present invention, a supply of process liquid is in communication with the plurality of liquid-dispensing nozzles.

In preferred embodiments of the apparatus according to the present invention, a supply of process liquid is in communication with the liquid dispenser.

In preferred embodiments of the apparatus according to the present invention, a radiant heating assembly is positioned such that a wafer-shaped article when mounted on the rotary chuck is positioned between the radiant heating assembly and the non-rotating plate.

In preferred embodiments of the apparatus according to the present invention, the radiant heating assembly comprises multiple LED lamps, and wherein the non-rotating plate comprises portions formed from quartz or sapphire.

In preferred embodiments of the apparatus according to the present invention, the contact surfaces are configured to contact an edge of a wafer-shaped article only at a side surface thereof.

In preferred embodiments of the apparatus according to the present invention, the contact surfaces face inwardly and are parallel to the rotational axis of the rotary chuck.

### BRIEF DESCRIPTION OF THE DRAWINGS

Other objects, features and advantages of the invention will become more apparent after reading the following detailed description of preferred embodiments of the invention, given with reference to the accompanying drawings, in which:

FIG. 1 is a plan view of a rotary chuck for use in an apparatus according to a first embodiment of the present invention; and

FIG. 2 is a cross-sectional view of an apparatus according to a first embodiment of the present invention, in which the rotary chuck is sectioned along the line II-II of FIG. 1.

### DETAILED DESCRIPTION OF PREFERRED EMBODIMENTS

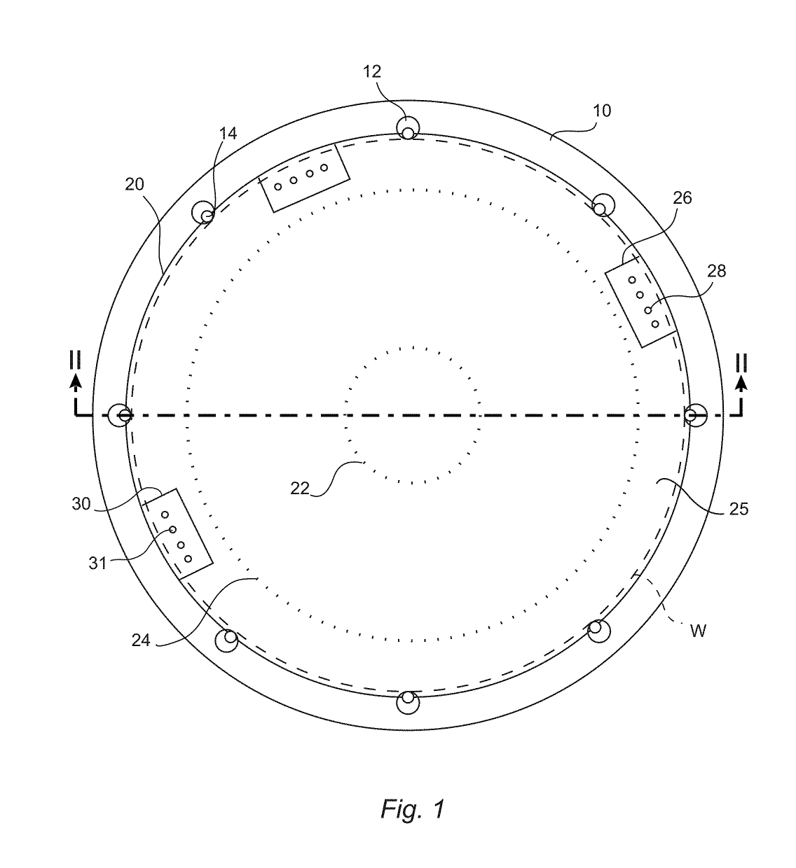

Referring now to FIG. 1, a rotary chuck 10 comprises a circular series of contact elements 12, which in this embodiment are eight in number, but which may be any desired number of three or more. A series of six contact elements 12 is preferred. The contact elements 12 each comprise a contact surface 14 at a distal end thereof, which contacts a wafer W when the chuck 10 is in use. The contact elements 12 could be gripping pins, but more preferably the contact surfaces 14 are smooth and parallel to the axis of rotation of the rotarty chuck 10, as they need to provide only lateral but not subjacent support for a wafer W.

The contact surfaces 14 of the contact elements 12 are eccentric to the axes of rotation of the contact elements 12, so that the surfaces 14 are movable between a radially outer non-contact position, for loading and unloading a wafer W, and a working position, as shown. The positioning of the contact elements 12 is such that the chuck 10 is configured to hold a wafer of a predetermined diameter, for example a 300 mm diameter or 450 mm diameter semiconductor wafer.

A stationary fluid distribution manifold 20 is positioned within the circle described by the contact elements 12, and beneath a wafer W when one is positioned on the chuck 10. Manifold 20 comprises an upper plate 25 that is likewise stationary, and in which are formed an inner series of discharge nozzles 22, and an outer series of discharge nozzle 24. Either or both of the series of nozzles 22, 24 could be formed instead as a single continuous annular nozzle, or a circular series of arcuate nozzles.

Three modular liquid nozzle assemblies 26, 30 are removably attached to the manifold 20 and upper plate 25, and each includes a series of liquid discharge orifices 28, 31 positioned so as to discharge process liquid upwardly, and, if desired, radially outwardly, onto the downwardly-facing surface of a wafer W, in the peripheral area thereof.

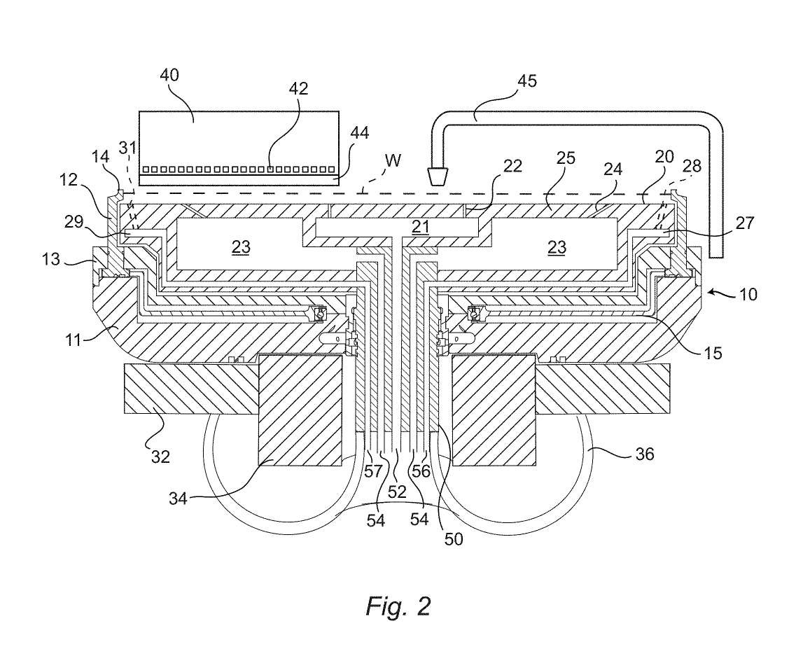

Turning now to FIG. 2, it can be seen that the rotary chuck 10 comprises a chuck base body made up of a lower part 11 and an upper part 13 that are rigidly interconnected. The chuck base body is mounted for motation about a stationary central post 50, which in turn is mounted on a support frame 36 of the apparatus. Also mounted on the support frame 36 is a stator 32, which cooperates with a rotor 34 secured to the chuck base body so as to drive the chuck 10 in rotation.

The fluid distribution manifold 20 including upper plate 25 is rigidly mounted to the stationary central post 50. The chuck 10 surrounds manifold 20. Chuck 10 also includes a ring gear 15 sandwiched between elements 11 and 13, which comprises a ring of outwardly projecting teeth coaxial with the chuck 10 and simultaneously engaging complementary teeth formed at the base of each contact element 12. Rotation of the chuck base body and ring gear 15 thereby rotates the series of contact elements 12 in unison.

As can be seen in FIG. 2, the contact elements 12 of this embodiment are crank-shaped, such that their upper and lower ends overlap the manifold 20 when viewed from above, but also include a radially-outwardly projecting intermediate portion that provides clearance for the contact elements 12 relative to the manifold 20.

Central post 50 comprises liquid conduits 56 and 57, which are supplied with process liquid from a supply thereof. Liquid conduits 56, 57 communicate with liquid conduits 27 and 29, respectively, formed in the fluid distribution manifold 20, which in turn communicate with the liquid nozzle assemblies 26 and 30, respectively, shown in FIG. 1. The modular nature of the assemblies 26 permits them to be easily removed and exchanged for cleaning, and for providing differently sized and shaped discharge orifices according to the process in question.

Central post 50 also includes gas conduits 54, which are connected to a source of gas, which is preferably nitrogen. Conduits 54 open at their downstream ends into the chamber 23 formed in manifold 20. Chamber 23 communicates with the circular series of discharge nozzles 24, which, as shown in FIG. 2, are bores formed in plate 25 that extend obliquely from a radially inner inlet to a radially outer outlet.

Central post 50 still further includes gas conduit 52, which is likewise connected to a source of gas, which again is preferably nitrogen. Conduit 52 opens at its downstream end into the chamber 21 formed in manifold 20. Chamber 21 communicates with the circular series of discharge nozzles 22, which, as shown in FIG. 2, are bores formed in plate 25 that extend axially through plate 25.

Also shown in FIG. 2 is a liquid dispenser 45 for dispensing liquid onto the upwardly-facing surface of wafer W. Dispenser 45 may for example take the form of a boom swing arm that moves the downwardly-depending discharge nozzle along an arc above the upper surface of a wafer to be processed, as well as to a rest position.

FIG. 2 also shows a heater 40, which is preferably a radiant heating assembly. More preferably, heater 40 comprises a multiplicity of blue LED heating elements 42, which are shielded from the process environment by a plate 44 that is made of material transparent to the radiation emitted by the LEDs 42, such as quartz or sapphire.

It will be observed in FIG. 2 that the surface 14 of contact elements 12 that touch the wafer W do so only at the outer peripheral edge of the wafer. In this embodiment, those surfaces are parallel to the rotation axis of chuck 10. As such, the contact elements 12 check the wafer W against lateral displacement, but do not provide subjacent support to the wafer. This arrangement allows a wafer W to be gripped in different positions at different axial distances from the upper plate 25.

In use, gas is supplied through conduits 54 into chamber 23 and discharged through nozzles 24. A wafer W is positioned above and parallel to the upper plate 25, preferably at a distance in the range of 0.3 to 3.0 mm. The flow rate of gas through the nozzles is adjusted so that the wafer W is supported according to the Bernoulli principle.

Loading and unloading of a wafer W may be assisted by supplying gas through conduit 52, which passes into chamber 21 and is discharged through the axial nozzles 22. Gas supply through nozzles 22 may be controlled independently of gas supply through nozzles 24. The supply may be alternate or simultaneous.

The above-described configuration of contact surface 14 aids in achieving a stable support of the wafer W in this manner, because the distance to the non-rotating plate is an equilibrium depending on the gas flow and the weight of the wafer-shaped article (further depending on gravity and mass). The parallel contact surface 14 can for example be a vertical plane or cylinder with generatrices parallel to the rotational axis of the rotary chuck. Consequently, the radial bearing of the wafer-shaped article is provided by the gripping elements, whereas the axial bearing is provided by the gas cushion. A horizontal notch in the contact surface would tend to limit axial displacement of the wafer W, and is preferably avoided. However, if a notch is utilized in the contact elements, it should be in the position corresponding to the equilibrium predicted for the gas flow and wafer weight in question.

The contact elements 20 are then closed by causing relative rotation of gear ring 15 and chuck base body 11, 13 in a manner known per se, whereafter the wafer W may be rotated by rotating the chuck base body 11, 13 and contact elements 12 in unison.

A typical process to be performed on the illustrated apparatus would be a bevel etch of a wafer, either alone or together with a backside etch. In such a process, a wafer W is positioned on the chuck with its device side facing down and its backside facing up. Etching liquid supplied through the conduits 56, 27 and discharged by discharge nozzles 28 of nozzle assemblies 26 will impinge on a defined peripheral region of the device side, thereby to provide a bevel etch. Thereafter rinsing liquid is supplied through the conduits 57, 29 and discharged by discharge nozzles 31 of nozzle assemblies 30.

If it is also desired to etch the backside of the wafer W, which faces upwardly, then process liquid can be dispensed from the dispenser 45. Etching is promoted by heating of the wafer, which is performed with heater 40.

Different wafers might require a different extent of bevel etch, for example, 2, 3 or 4 mm. The provision of the modular liquid nozzle assemblies 26 also permits the rapid exchange of assemblies whose nozzles are positioned differently depending on the radial extent of the desired bevel etch.

While the present invention has been described in connection with various preferred embodiments thereof, it is to be understood that those embodiments are provided merely to illustrate the invention, and that the invention is not limited to those embodiments, but rather includes that which is encompassed by the true scope and spirit of the appended claims.

What is claimed is:

1. An apparatus for processing wafer-shaped articles, comprising a rotary chuck adapted to receive a wafer-shaped article of a predetermined diameter thereon, the rotary chuck comprising a series of contact elements surrounding a wafer-shaped article when mounted on the rotary chuck, said series of contact elements rotating in a circle as the rotary chuck rotates, and each of said series of contact elements being movable so as to move a contact surface of a corresponding contact element from a radially outer loading position to a radially inner contact position;
said apparatus further comprising a non-rotating plate, said non-rotating plate being positioned interiorly of said series of contact elements, covering at least 90% of the area surrounded by said series of contact elements and comprising a gas supply, said gas supply being configured to supply gas so as to support a wafer-shaped article without contacting said non-rotating plate according to the Bernoulli principle.

2. The apparatus according to claim 1, wherein the gas supply is an annular gas supply directed radially outwardly in relation to an axis of rotation of said rotary chuck.

3. The apparatus according to claim 1, wherein the non-rotating plate is secured on a stationary central post.

4. The apparatus according to claim 1, wherein said non-rotating plate is generally circular and mounted coaxially with an axis of rotation of said rotary chuck, said rotary chuck having a diameter that is greater than said predetermined diameter.

5. The apparatus according to claim 1, wherein said contact surface faces radially inwardly in said contact position and is parallel to the rotational axis of the rotary chuck.

6. The apparatus according to claim 1, wherein said rotary chuck comprises a chuck base body mounted for rotation about said central post, said chuck base body surrounding a liquid distribution manifold comprising said non-rotating plate.

7. The apparatus according to claim 6, wherein each of said series of contact elements comprises a shaft projecting from said chuck base body, and wherein said contact surface projects radially inwardly from a distal end of said shaft so as to overlie said non-rotating plate in said contact position.

8. The apparatus according to claim 1, wherein said gas supply is an annular array of gas supply nozzles comprising a circular series of bores that open on a surface of said non-rotating plate that faces a wafer-shaped article when mounted on said rotary chuck, each of said circular series of bores extending from said surface interiorly of said non-rotating plate at an oblique angle relative to an axis of rotation of said rotary chuck.

9. The apparatus according to claim 1, wherein said non-rotating plate further comprises a plurality of liquid-dispensing nozzles positioned radially outwardly of said gas supply, and directed toward an edge region of a wafer-shaped article when positioned on said rotary chuck.

10. The apparatus according to claim 9, wherein said plurality of liquid dispensing nozzles are comprised by a modular nozzle block that is attachable to and detachable from said non-rotating plate.

11. The apparatus according to claim 1, wherein the series of contact elements is a series of pins, each of said series of pins being rotatable about a respective pin axis so as to move a contact surface of a corresponding pin from a radially outer loading position to a radially inner contact position.

12. The apparatus according to claim 1, further comprising a liquid dispenser positioned so as to dispense liquid onto a side of a wafer-shaped article that faces away from said non-rotating plate when positioned on said rotary chuck.

13. The apparatus according to claim 1, wherein said gas supply comprises an annular array of gas supply nozzles or an annular gas supply nozzle.

14. The apparatus according to claim 1, further comprising a supply of inert gas in communication with said gas supply.

15. The apparatus according to claim 9, further comprising a supply of process liquid in communication with said plurality of liquid-dispensing nozzles.

16. The apparatus according to claim 12, further comprising a supply of process liquid in communication with said liquid dispenser.

17. The apparatus according to claim 1, further comprising a radiant heating assembly positioned such that a wafer-shaped article when mounted on said rotary chuck is positioned between said radiant heating assembly and said non-rotating plate.

18. The apparatus according to claim 17, wherein said radiant heating assembly comprises multiple LED lamps, and wherein said non-rotating plate comprises portions formed from quartz or sapphire.

19. The apparatus according to claim 1, wherein said contact surfaces are configured to contact an edge of a wafer-shaped article only at a side surface thereof.

20. The apparatus according to claim 19, wherein said contact surfaces face inwardly and are parallel to the rotational axis of the rotary chuck.
